(19) United States
(12) Patent Application Publication
(10) Pub. No.: US 2025/0233312 A1
(43) Pub. Date: Jul. 17, 2025

(54) WAVEGUIDE ANTENNA STRUCTURE

(71) Applicant: HL KLEMOVE CORP., Incheon (KR)

(72) Inventors: Hyunseok LEE, Incheon (KR); Sungjoon HEO, Incheon (KR)

(21) Appl. No.: 19/017,373

(22) Filed: Jan. 10, 2025

(30) Foreign Application Priority Data
Jan. 11, 2024 (KR) 10-2024-0004566

(51) Int. Cl. H01Q 13/08; H01Q 5/55

(52) U.S. Cl. CPC H01Q 13/085; H01Q 5/55

(57) ABSTRACT

A waveguide antenna structure is provided. The waveguide antenna structure includes a base layer in which a feeding hole is formed; a waveguide layer which is stacked on top of the base layer and is provided with a waveguide in communication with the feeding hole; an antenna layer which is stacked on top of the waveguide layer and is provided with an antenna for transmitting or receiving signals passing through the feeding hole and the waveguide to or from the outside; and a first via wall layer which includes a plurality of first via holes that are stacked on top of the antenna layer and are used to change the path of radio waves that are transmitted or received through the antenna.

### CROSS-REFERENCE TO RELATED APPLICATION

This application claims priority to and the benefit of Korean Patent Application No. 10-2024-0004566, filed on Jan. 11, 2024, the disclosure of which is incorporated herein by reference in its entirety.

### BACKGROUND

### 1. Technical Field

The present disclosure relates to a waveguide antenna structure, and more specifically to a PCB stacked waveguide antenna structure which is provided with a via wall layer.

### 2. Discussion of Related Art

Recently, antennas used in radar have changed from the PCB type to the waveguide type and are evolving.

Conventional waveguide type antennas are manufactured with an aluminum structure or a plastic injection structure, and in this structure, a structure is needed to transfer a signal from a microstrip to a waveguide in order to transmit a signal to the antenna.

However, this method has disadvantages in terms of price, antenna production and assembly, and signal loss.

Therefore, there is a need to develop a waveguide antenna technology that does not have a structure for transitioning from a microstrip to a waveguide in waveguide-type antennas.

Additionally, in terms of developing such a waveguide antenna structure, the waveguide antenna technology that allows various design of signal characteristics and signal paths of RF signals is needed.

### SUMMARY

An object of the present disclosure is to provide a waveguide antenna structure using a direct power feeding method.

Another object of the present disclosure is to provide an antenna structure in which a waveguide is formed by stacking PCBs.

Still another object of the present disclosure is to provide a waveguide antenna structure that can change the path of an RF signal or change signal characteristics by stacking an additional PCB with via holes formed on top of a waveguide antenna formed by stacking PCBs, and providing a wall formed with via holes.

The objects of the present disclosure are not limited to the above-described objects, and other objects that are not mentioned will be able to be clearly understood by those skilled in the art to which the present disclosure pertains from the following description.

According to an aspect of the present disclosure, provided is a waveguide antenna structure, including a base layer in which a feeding hole is formed; a waveguide layer which is stacked on top of the base layer and is provided with a waveguide in communication with the feeding hole; an antenna layer which is stacked on top of the waveguide layer and is provided with an antenna for transmitting or receiving signals passing through the feeding hole and the waveguide to or from the outside; and a first via wall layer which includes a plurality of first via holes that are stacked on top of the antenna layer and are used to change the path of radio waves that are transmitted or received through the antenna.

In this case, each of the first via wall layer, the antenna layer, the waveguide layer and the base later may include a board layer; and a first protective layer and a second protective layer which are respectively stacked on an upper surface and a lower surface of the board layer.

In this case, the board layer may be made of an FR-4 material, and the first protective layer and the second protective layer may be made of a material that is conductive and capable of forming plating.

In this case, a plurality of second via holes which penetrate the base layer, the waveguide layer and the antenna layer that are stacked together may be formed in the base layer, the waveguide layer and the antenna layer, wherein when viewed in a first direction in which the layers are stacked, the plurality of second via holes may be arranged to surround the feeding hole, the waveguide and the antenna, and wherein the plurality of first via holes of the first via wall layer may be formed on a side part of the antenna along the extension direction of the waveguide, and be disposed at a greater distance from the antenna than the plurality of second via holes.

In this case, the plurality of second via holes may be arranged in a row in a rectangular shape, and the arrangement length of the plurality of second via holes that are arranged in the extension direction of the waveguide may be longer than the length arranged in the width direction.

In this case, the distance between the plurality of second via holes and the plurality of first via holes may be 1.52 or less.

In this case, the height of the plurality of first via holes may be 1.52 or less.

In this case, the plurality of first via holes may be arranged in a row on one side part or both side parts of the waveguide in the extension direction of the waveguide.

In this case, the plurality of first via holes may be arranged in two rows on one side part or both side parts of the waveguide such that neighboring via holes are staggered in the extension direction of the waveguide.

In this case, the board layer of the first via wall layer may be provided with a first opening which includes an outer area of an area in which the plurality of second via holes surround the feeding hole, the waveguide and the antenna, and is wider than the outer area, and the plurality of first via holes are formed outside the first opening.

In this case, the first via wall layer may be formed to block an upper part of the area where the plurality of second via holes surround the feeding hole, the waveguide and the antenna.

In this case, an adhesive layer may be respectively interposed between the base layer, the waveguide layer, the antenna layer and the first via wall layer.

In this case, the waveguide antenna structure may further include a second via wall layer which is stacked on top of the first via wall layer and includes a plurality of third via holes for changing the path of the radio wave, wherein a board layer of the second via wall layer may be provided with a second opening which includes an outer area of the first opening and is wider than the outer area, and the plurality of third via holes may be formed outside the second opening.

Meanwhile, the waveguide antenna structure may further include a second via wall layer which is stacked on top of the first via wall layer and includes a plurality of third via holes for changing the path of the radio wave, wherein a board layer of the second via wall layer may be formed such that the plurality of third via holes block an area surrounding the feeding hole, the waveguide and the antenna, and the plurality of third via holes may be disposed to be spaced farther apart from the plurality of second via holes than the plurality of first via holes.

According to another aspect of the present disclosure, provided is a waveguide antenna structure, including a base layer in which a feeding hole is formed; a waveguide layer which is stacked on top of the base layer and is provided with a waveguide in communication with the feeding hole; an antenna layer which is stacked on top of the waveguide layer and is provided with an antenna for transmitting or receiving signals passing through the feeding hole and the waveguide to or from the outside; and at least one via wall layer which is stacked on top of the antenna layer and is used to change the path of radio waves that are transmitted or received through the antenna.

In this case, each of the at least one via wall layer may include a plurality of via holes that are formed on a side part of the antenna along the extension direction of the waveguide.

In this case, each of the plurality of via holes that are formed in the at least one via wall layer may be arranged in a row on one side part or both side parts of the antenna.

In this case, among the plurality of via holes that are formed in the at least one via wall layer, the plurality of via holes in the via wall layer that is closer to the antenna layer may be disposed to be closer to the antenna than the plurality of via holes in the via wall layer that is disposed farther from the antenna layer.

In this case, the at least one or via wall layer may respectively include an opening which includes an outer area of an area surrounding the feeding hole, the waveguide and the antenna when viewed in the vertical direction, and is wider than the outer area, and the area of the opening of the via wall layer far from the antenna layer may be formed to be wider than the area of the opening of the via wall layer close to the antenna layer.

Meanwhile, the at least one via wall layer may be formed to block an area surrounding the feeding hole, the waveguide and the antenna.

### BRIEF DESCRIPTION OF THE DRAWINGS

The above and other objects, features and advantages of the present disclosure will become more apparent to those of ordinary skill in the art by describing in detail exemplary embodiments thereof with reference to the accompanying drawings, in which:

FIG. 1 is a perspective view of a PCB stacked waveguide antenna using a direct power feeding method according to the first example of the present disclosure;

FIG. 2 is a cross-sectional view taken along the line I-I′ of FIG. 1 of the PCB stacked waveguide antenna using a direct power feeding method according to the first example of the present disclosure;

FIG. 3 is a perspective view of the PCB stacked waveguide antenna using a direct power feeding method in FIG. 1 with a via wall layer removed;

FIG. 4 is a plan view of the PCB stacked waveguide antenna using a direct power feeding method in FIG. 1 with a via wall layer removed;

FIG. 5 is a bottom view of the PCB stacked waveguide antenna using a direct power feeding method in FIG. 1 with a via wall layer removed;

FIG. 6 is a cross-sectional view taken along the II-II′ direction of the PCB stacked waveguide antenna using a direct power feeding method in FIG. 3 with a via wall layer removed;

FIG. 7 is a cross-sectional view taken along the III-III′ direction of the PCB stacked waveguide antenna using a direct power feeding method according to an exemplary embodiment of the present disclosure in FIG. 3 with a via wall layer removed;

FIG. 8 is a plan view showing the modified example of a via hole of the PCB stacked waveguide antenna using a direct power feeding method in FIG. 1 with a via wall layer removed;

FIG. 9 is a cross-sectional view showing the distance relationship between a waveguide and a via hole of the PCB stacked waveguide antenna using a direct power feeding method in FIG. 1 with a via wall layer removed;

FIG. 10 is a cross-sectional view showing various modified examples of a waveguide of the PCB stacked waveguide antenna using a direct power feeding method according to the first example of the present disclosure;

FIG. 11 is a beam pattern graph of the PCB stacked waveguide antenna when there is no via wall layer;

FIG. 12 is a beam pattern graph of the PCB stacked waveguide antenna using the direct power supply method according to the first example of the present disclosure, and is a graph showing simulation results according to changes in the height of the via wall layer;

FIG. 13 is a beam pattern graph of the PCB stacked waveguide antenna using the direct power supply method according to the first example of the present disclosure, and is a graph showing simulation results according to changes in the position of the via wall layer;

FIG. 14 is a perspective view of the PCB stacked waveguide antenna using a direct power feeding method according to the second example of the present disclosure;

FIG. 15 is a cross-sectional view taken along the line IV-IV′ of FIG. 14 of the PCB stacked waveguide antenna using a direct power feeding method according to the second example of the present disclosure;

FIG. 16 is a perspective view of the PCB stacked waveguide antenna using a direct power feeding method according to the third example of the present disclosure;

FIG. 17 is a cross-sectional view taken along the line V-V′ of FIG. 16 of the PCB stacked waveguide antenna using a direct power feeding method according to the third example of the present disclosure;

FIG. 18 is a perspective view of the PCB stacked waveguide antenna using a direct power feeding method according to the fourth example of the present disclosure;

FIG. 19 is a cross-sectional view taken along the line VI-VI of FIG. 18 of the PCB stacked waveguide antenna using a direct power feeding method according to the fourth example of the present disclosure;

FIG. 20 is a cross-sectional view of the first modified example of the PCB stacked waveguide antenna using a direct power feeding method according to the first example of the present disclosure;

FIG. 21 is a plan view of the second modified example of the PCB stacked waveguide antenna using a direct power feeding method according to the first example of the present disclosure; and

FIG. 22 is a plan view of the third modified example of the PCB stacked waveguide antenna using a direct power feeding method according to the first example of the present disclosure.

### DETAILED DESCRIPTION OF EXEMPLARY EMBODIMENTS

Hereinafter, embodiments of the present disclosure will be described in detail so that those skilled in the art to which the present disclosure pertains can easily carry out the embodiments. The present disclosure may be implemented in many different forms and is not limited to the embodiments described herein. In order to clearly describe the present disclosure, portions not related to the description are omitted from the accompanying drawings, and the same or similar components are denoted by the same reference numerals throughout the specification.

The words and terms used in the specification and the claims are not limitedly construed as their ordinary or dictionary meanings, and should be construed as meaning and concept consistent with the technical spirit of the present disclosure in accordance with the principle that the inventors can define terms and concepts in order to best describe their invention.

In the specification, it should be understood that the terms such as “comprise” or “have” are intended to specify the presence of features, numbers, steps, operations, components, parts, or combinations thereof described in the specification and do not preclude the possibility of the presence or addition of one or more other features, numbers, steps, operations, components, parts, or combinations thereof.

The words and terms used in the present specification and claims are not to be construed as limited in their usual or dictionary meanings, but according to the principle that the inventor can define terms and concepts in order to explain his or her invention in the best way, they must be interpreted with meanings and concepts that are consistent with technical ideas.

Therefore, the exemplary embodiments described in the present specification and the configuration illustrated in the drawings correspond to a preferred exemplary embodiment of the present disclosure, and do not represent the entire technical idea of the present disclosure, and thus, the corresponding configuration may have various equivalents and modifications to replace the same at the time of filing of the present disclosure.

The waveguide antenna structure according to an exemplary embodiment of the present disclosure is a waveguide antenna structure which is configured such that after forming a pipe through routing on a stacked PCB and forming a waveguide by forming via holes on both sides of the pipe, it has a base layer provided with a feeding hole to enable direct feeding of power to the waveguide and an antenna layer to transmit or receive RF signals transmitted from the waveguide.

In this case, the waveguide antenna structure according to an exemplary embodiment of the present disclosure is configured to form a wall through which signals can be reflected by stacking a PCB including a via hole on top of the antenna layer.

Accordingly, the waveguide antenna structure according to an exemplary embodiment of the present disclosure has a simple structure and is configured to directly feed power, thereby reducing signal loss.

In addition, the pattern or path of signals may be changed by using a via wall formed on top of the antenna layer.

Hereinafter, the waveguide antenna structure according to an exemplary embodiment of the present disclosure will be described in detail with different drawings. In the present specification, the thickness of each layer constituting the waveguide antenna structure is exaggerated for the clarity of description.

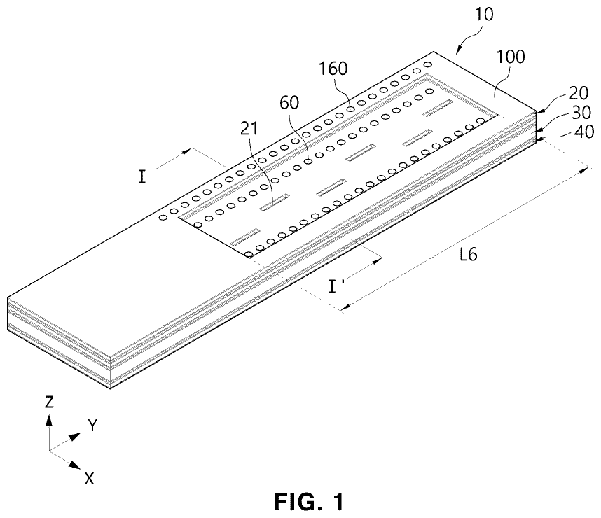

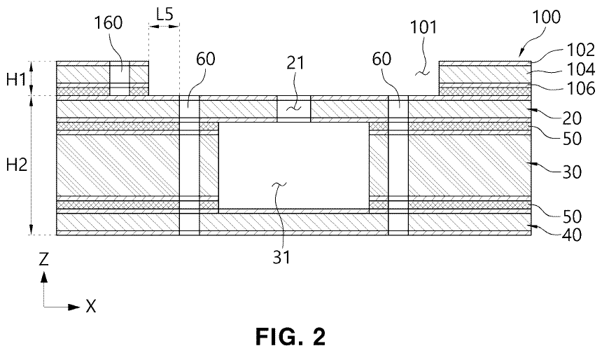

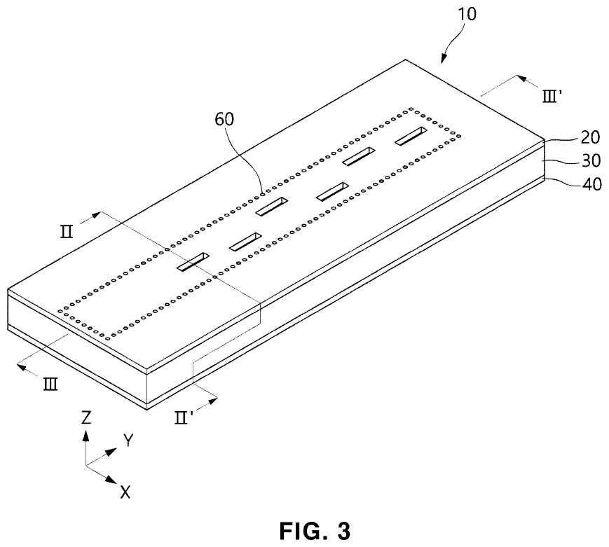

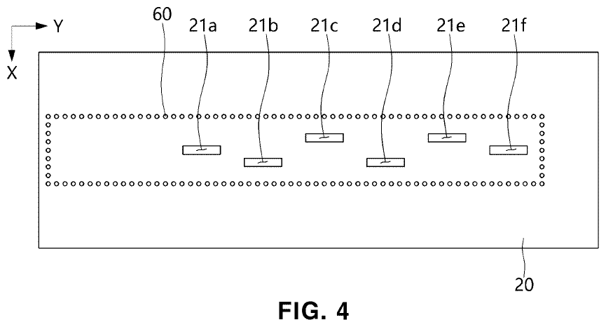

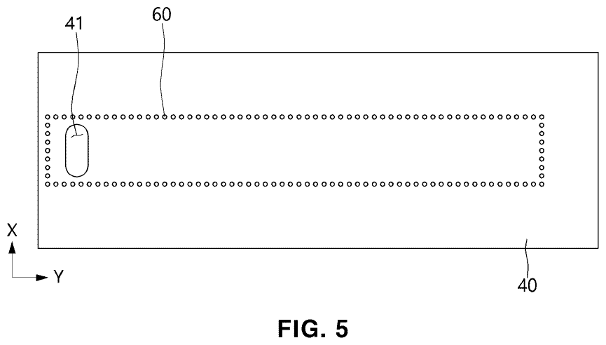

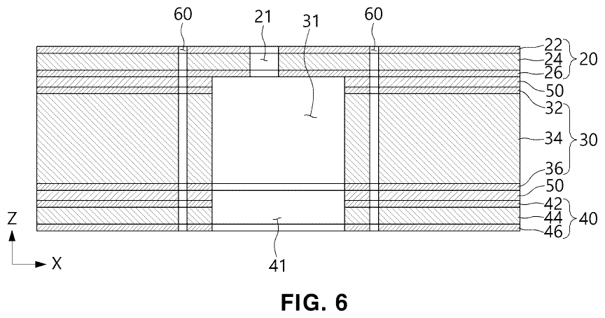

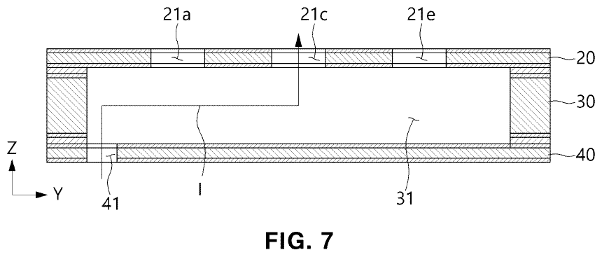

FIG. 1 is a perspective view of a PCB stacked waveguide antenna using a direct power feeding method according to the first example of the present disclosure, FIG. 2 is a cross-sectional view taken along line I-I′ of FIG. 1 of the PCB stacked waveguide antenna using a direct power feeding method according to the first example of the present disclosure, and FIG. 3 is a perspective view of the PCB stacked waveguide antenna using a direct power feeding method in FIG. 1 with a via wall layer removed. FIG. 4 is a plan view of the PCB stacked waveguide antenna using a direct power feeding method in FIG. 1 with a via wall layer removed. FIG. 5 is a bottom view of the PCB stacked waveguide antenna using a direct power feeding method in FIG. 1 with a via wall layer removed. FIG. 6 is a cross-sectional view taken along the II-II′ direction of the PCB stacked waveguide antenna using a direct power feeding method in FIG. 3 with a via wall layer removed. FIG. 7 is a cross-sectional view taken along the III-III′ direction of the PCB stacked waveguide antenna using a direct power feeding method according to an exemplary embodiment of the present disclosure in FIG. 3 with a via wall layer removed.

Referring to FIGS. 1 to 7, the waveguide antenna structure 10 according to an exemplary embodiment of the present disclosure includes a via wall layer 100, an antenna layer 20, a waveguide layer 30 and a base layer 40.

Hereinafter, in terms of describing the waveguide antenna structure 10 according to an exemplary embodiment of the present disclosure, the antenna layer 20, waveguide layer 30 and base layer 40, which are the basic structures of the waveguide antenna structure, are first described, and then, the via wall layer 100 disposed on top of the antenna layer 20 will be described in detail.

Referring to FIGS. 2 to 4, the antenna layer 20 is a layer which is disposed on top of the waveguide layer 30 in the waveguide antenna structure 10 according to an exemplary embodiment of the present disclosure, and it is a layer where RF signals that are transmitted through a waveguide to be described below are transmitted or received.

In an exemplary embodiment of the present disclosure, the antenna formed on the antenna layer 20 may be a slot antenna. However, the antenna formed on the antenna layer 20 is not limited thereto, and various types of antennas that are capable of transmitting or receiving RF signals, such as a horn antenna or a patch antenna, may be used.

In the present exemplary embodiment, referring to FIGS. 1 to 4, the slot antenna formed on the antenna layer 20 may include a plurality of antenna holes 21.

As illustrated in FIGS. 1 to 4, the plurality of antenna holes 21 may include six slots 21a, 21b, 21c, 21d, 21e, 21f that are arranged in two rows in the y-axis direction as seen in FIG. 4.

In the present exemplary embodiment, six slots 21a, 21b, 21c, 21d, 21e, 21f are formed to penetrate the antenna layer 20 in the vertical direction. In this case, the six slots 21a, 21b, 21c, 21d, 21e, 21f are arranged in a staggered manner between neighboring slots to transmit and receive RF signals that are transmitted through the waveguide.

The shape, size, and arrangement of the six slots may be changed depending on the operating frequency and performance of the transmitted or received RF signal. Since the arrangement and configuration of such a slot antenna are known configurations, the detailed descriptions thereof will be omitted.

Referring to FIG. 6, in an exemplary embodiment of the present disclosure, the antenna layer 20 may include a first board 24 and as seen in FIG. 6, a first protective layer 22 and a second protective layer 26 which are respectively formed on an upper side surface and a lower side surface of the first board 24.

In this case, the first board 24 may be formed of a material such as FR-4 as an example. However, the material forming the first board 24 is not limited thereto, and the first board 24 may be formed of a known material that is capable of forming a board.

In this case, the first board 24 may have a thin plate shape. In this case, the thickness of the first board 24 may vary depending on the operating frequency and performance of the antenna and waveguide, and it may change depending on the design.

Meanwhile, the first protective layer 22 and the second protective layer 26 of the first board 24 may be formed of a material that is conductive and can form plating, for example, a combination of copper foil and copper plating layer. The thickness of the antenna layer 20 may also vary depending on the thicknesses of the first protective layer 22 and the second protective layer 26.

Referring to FIG. 6, a waveguide layer 30 is coupled to a lower part of the antenna layer 20.

The waveguide layer 30 may include a second board 34 and a first protective layer 32 and a second protective layer 36 which are respectively formed on an upper side surface and a lower side surface of the second board 34.

The second board 34 may be formed of the same material as the first board 24, and for example, FR-4. However, the material of the second board 34 is not limited thereto. In addition, the first protective layer 32 and the second protective layer 36 that are formed on the upper side surface and lower side surface of the second board 34 may be formed in the same way as the first protective layer 22 and the second protective layer 26 that are formed on the first board 34.

Referring to FIGS. 6 and 7, a waveguide 31 is formed on the second board 34.

As can be seen in FIGS. 6 and 7, the waveguide 31 is formed to have a rectangular cross-section with a length extending in the y-axis direction, and it may be also formed to have a rectangular cross-section with a predetermined width and height in the x-axis direction. The interior of the waveguide 31 may be filled with air. In this case, the design of the width and height in the x-axis direction and the length in the y-axis direction of the waveguide 31 may vary depending on the frequency and performance of the RF signal. In FIG. 5, the arrow (I) indicates the direction of movement of RF signals moving from the base layer to the antenna layer. According to an exemplary embodiment of the present disclosure, a plurality of waveguides may be formed on the second board to form a waveguide antenna structure, and each of the plurality of waveguides may be individually connected to a plurality of feeding holes by corresponding to each other. In this case, each of the plurality of waveguides may be used for transmission or reception. One waveguide antenna structure may include at least one waveguide for transmission and at least one waveguide for reception. In the present specification, for simplification of the drawings, a structure in which one waveguide 31 is connected to one feeding hole 41 in the waveguide antenna structure is illustrated.

In an exemplary embodiment of the present disclosure, the antenna layer 20 and the waveguide layer 30 may be adhered by an adhesive layer 50. For example, the adhesive layer 50 may be formed by using an adhesive such as a bonding sheet, prepreg or glue.

Meanwhile, referring to FIGS. 6 and 7, a base layer 40 is coupled to a lower part of the waveguide layer 30.

The base layer 40 may include a third board 44 and a first protective layer 42 and a second protective layer 46 which are formed on an upper surface and a lower surface of the third board 44.

The third board 44 may be formed of an FR-4 material similarly to the first board 24 and the second board 34. However, the material forming the third board 44 is not limited thereto, and the third board 44 may be formed of a known material that is capable of forming a board.

The third board 44 may have a thin plate shape. The first protective layer 42 and the second protective layer 46 that are formed on the upper surface and lower surface of the third board 44 may be formed in the same way as the first protective layer 32 and the second protective layer 36 which are formed on the first board and second boards.

In an exemplary embodiment of the present disclosure, the base layer 40 is formed with a feeding hole 41 penetrating in the vertical direction. The feeding hole 41 is a hole through which an RF signal that is fed directly from an RF signal generator (not illustrated) passes.

In an exemplary embodiment of the present disclosure, referring to FIG. 7, the upper side of the feeding hole 41 is connected to one end of the waveguide 31, and accordingly, the RF signal may pass through the feeding hole 41, pass through the inside of the waveguide 31 and be radiated to the outside through the antenna layer 20.

The area of the area where the feeding hole 41 is connected to the waveguide 31 may vary depending on the antenna design. However, according to an exemplary embodiment of the present disclosure, when the upper side of the feeding hole 41 is not connected to the waveguide 31 in communication, the RF signal transmitted through the feeding hole 41 may not pass through the inside of the waveguide 31, and thus, the upper side of the feeding hole 41 must be in communication with the waveguide 31.

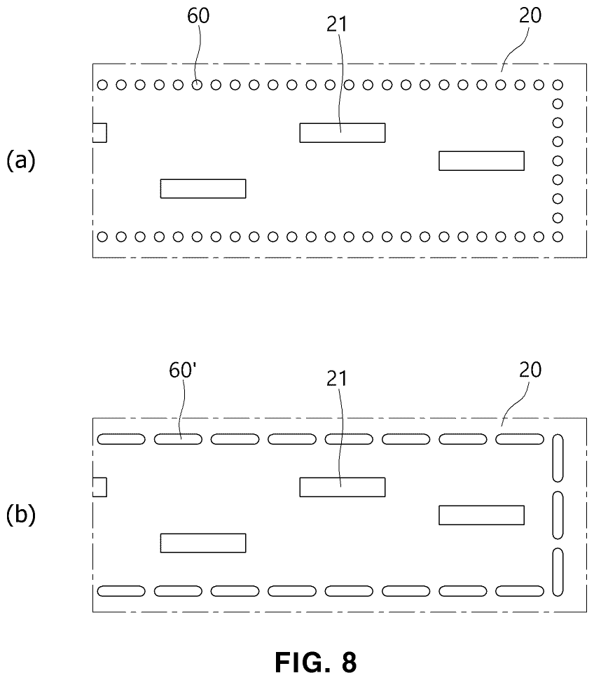

FIG. 8 is a plan view showing the modified example of a via hole of the PCB stacked waveguide antenna structure 10 using a direct power feeding method according to an exemplary embodiment of the present disclosure. FIG. 8(a) is a view in which the via hole 60 is circular, and FIG. 8(b) is a view in which the via hole 60′ is oval.

Referring to FIGS. 3, 6 and 8(a), in an exemplary embodiment of the present disclosure, the base layer 40, the waveguide layer 30 and the antenna layer 20 are formed with a plurality of via holes penetrating the three layers.

In this case, in an exemplary embodiment of the present disclosure, referring to FIG. 3, when viewed in the z-axis direction, a plurality of via holes 60 are arranged to surround the feeding hole 41, the waveguide 31 and the antenna hole 21.

In this case, referring to FIGS. 3 and 4, in an exemplary embodiment of the present disclosure, the plurality of via holes 60 are arranged in a rectangular shape extending along the extension direction of the waveguide 31, that is, the y-axis direction.

In this case, the plurality of via holes 60 may have a circular shape as illustrated in FIG. 8(a), an oval shape as illustrated in FIG. 8(b), or a quadrangle, square or rectangular shape (not illustrated). In this case, the extended length of the oval or rectangular via hole may be changed depending on the design.

The plurality of via holes 60 are provided to prevent radio wave leakage that is generated due to a gap between layers formed by an adhesive layer, when the three layers consisting of the antenna layer 20, the waveguide layer 30 and the base layer 40 are bonded by an adhesive layer 50.

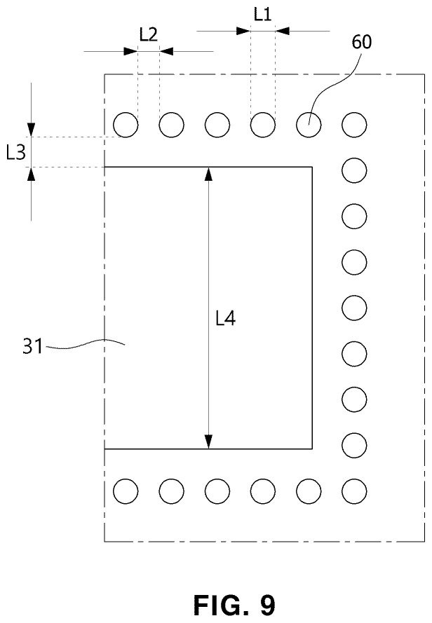

FIG. 9 is a cross-sectional view showing the distance relationship between the waveguide 31 and the via hole 60 of the PCB stacked waveguide antenna structure 10 using a direct power feeding method according to an exemplary embodiment of the present disclosure.

According to an exemplary embodiment of the present disclosure, the via hole 60 is a structure to prevent radio wave leakage in a portion where the plating layer is not formed, and it is desirable to maintain a gap through which the operating frequency of the RF signal does not pass.

To this end, it is desirable that the gap (L2) between neighboring via holes 60 is designed to be ½λ or less of the frequency of the RF signal passing through the waveguide 31. The gap between the via holes 60 may be designed based on the diameter, shape and location of the via holes 60.

Meanwhile, referring to FIG. 9, the distance (L3) between the waveguide 31 and the via hole 60 may be formed to be at least 0.05 mm or more, and it may be designed by taking the operating frequency into consideration upon designing. If the distance (L3) between the waveguide 31 and the via hole 60 is too close, it may be difficult to manufacture the via hole 60.

In addition, since the width of the waveguide 31 can be designed according to the diameter (L1), shape, size and location of the via hole 60, the width (L4) of the waveguide 31 may be designed according to the operating frequency.

In this case, the width (L4) of the waveguide 31 may be designed to have a small value as the operating frequency of the RF signal increases.

Meanwhile, according to an exemplary embodiment of the present disclosure, as can be seen in FIGS. 1 and 2, a via wall layer 100 is coupled to an upper part of the antenna layer 20. In an exemplary embodiment of the present disclosure, the via wall layer 100 may include a fourth board 104 and a first protective layer 102 and a second protective layer 106 which are respectively formed on an upper side surface and a lower side surface of the fourth board 104 as seen in FIG. 2.

In this case, the fourth board 104 may be formed of a material such as FR-4 as an example. However, the material forming the fourth board 104 is not limited thereto, and the fourth board 104 may be formed of a known material that is capable of forming a board.

In this case, referring to FIG. 2, the fourth board 104 may be formed in a thin plate shape. In this case, the thickness of the fourth board 104 may vary depending on the operating frequency and performance of the antenna and waveguide, and it may change depending on the design.

Meanwhile, the first protective layer 102 and the second protective layer 106 of the fourth board 104 may be formed of a material that is conductive and can form plating, for example, a combination of copper foil and copper plating layer.

In the first example of the present disclosure, a quadrangle-shaped opening 101 is formed on the fourth board 104. In this case, the opening 101 may be formed in the upper part of the outer area of the rectangular area formed by the via holes that are formed to surround the antenna layer 20 to be wider than the rectangular area.

In this case, according to an exemplary embodiment of the present disclosure, as illustrated in FIGS. 1 and 2, a plurality of via holes 160 are arranged in a row along one corner of the quadrangle-shaped opening 101 in the via wall layer 100 to form a via wall. The shape and size of the via hole 160 forming the via wall and the gap and arrangement between neighboring via holes 160 may be formed to be identical or similar to the shape and size of the via hole 60 formed to block a signal through the above-described waveguide layer 30, the gap and arrangement between neighboring via holes 60 and the like.

Hereinafter, in terms of describing the first example of the present disclosure, it will be described by defining the via hole formed on the fourth board 104 that is most adjacently coupled to the top of the antenna layer 20 to form a via wall as a first via hole 160, defining the via wall layer 100 in which the first via hole 160 is formed as a first via wall layer 100, and defining the via hole 60 penetrating the waveguide layer 30 as a second via hole 60.

Referring to FIG. 2, in an exemplary embodiment of the present disclosure, when compared to the height (H2) of the second via hole 60 formed to penetrate through the antenna layer 20, the waveguide layer 30 and the base layer 40, the height (H1) of the first via hole 160 formed on the first via wall layer 100 may be formed to be low.

In this case, the plurality of first via holes 160 of the first via wall layer 100 are formed on a side part of the antenna along the extension direction of the waveguide 31, and they may be placed at a greater distance than the plurality of second via holes 60 from the antenna.

In this case, the distance (L5 in FIG. 2) from the plurality of second via holes 60 to the plurality of first via holes 160 may be 1.52 or less. If the distance (L5 in FIG. 2) between the plurality of first via holes 160 is 1.52 or more, the effect of arranging the plurality of first via holes may be reduced.

Additionally, the height (H1) of the plurality of first via holes 160 may be 1.52 or less. The height (H1) of the plurality of first via holes 160 may be designed in consideration of the manufacturable thickness of the board and the effect on performance, and if it is 1.52 or less, it is possible to simultaneously satisfy manufacturability and performance.

The distance between the plurality of first via holes 160 and the plurality of second via holes 60 and the height of the plurality of first via holes 160 may be designed and selected to be variously changed in consideration of the pattern and frequency waveform of antenna signals to be designed.

Meanwhile, according to the first example of the present disclosure, the plurality of first via holes 160 may be formed on one side part of the waveguide 31 as in an exemplary embodiment of the present disclosure, for example, on the left side of the extension direction (y-axis direction) of the waveguide as seen in FIG. 1.

In this case, as can be seen in FIG. 1, the first via holes 160 formed in a row on one side part of the waveguide 31 may be arranged to form a wall which extends to be longer than the extension direction length of the opening (L6 in FIG. 1).

Meanwhile, according to an exemplary embodiment of the present disclosure, the waveguide formed in the waveguide layer may be formed in various forms. Hereinafter, this will be explained by using different drawings.

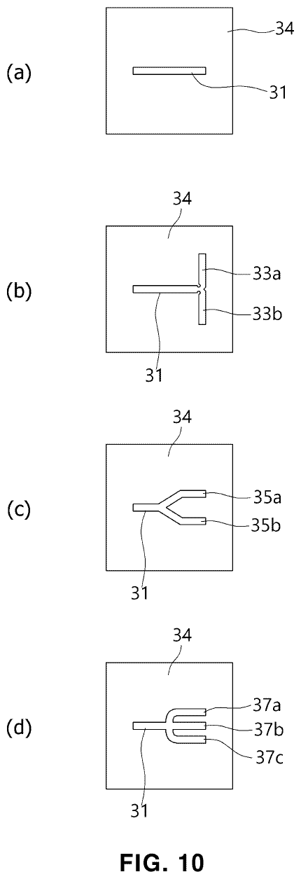

FIG. 10 is a cross-sectional view showing various modified examples of the waveguide of the PCB stacked waveguide antenna structure using a direct power feeding method according to an exemplary embodiment of the present disclosure. FIG. 10(a) is an example in which a straight waveguide is formed, and FIGS. 10(b) to 10(d) are examples in which two or more distribution waveguides are connected to the waveguide.

Referring to FIG. 10, as a modified example of an exemplary embodiment of the present disclosure, the waveguide 31 may include two or more distribution waveguides (33a and 33b in FIGS. 10(b), 35a and 35b in FIG. (c), and 37a, 37b, 37c in FIG. 10(d)) on the other end which is spaced apart from one end where the feeding hole 41 is connected.

In this case, as illustrated in FIG. 10(b), the first distribution waveguide 33a and the second distribution waveguide 33b may be arranged at intervals of 180 degrees, or as illustrated in FIG. 10(c), the first distribution waveguide 35a and the second distribution waveguide 35b may be arranged side by side to extend in the y-axis direction, or as illustrated in FIG. 9(b), 3 distribution waveguides 37a, 37b, 37c may be arranged side by side to extend in the y-axis direction.

As the distribution waveguide is formed in this way, the pattern of the gain of the RF signal may vary.

The shape and number of such waveguides and distribution waveguides may vary depending on the size of the entire antenna module, antenna placement and requirements.

In this case, when the number of distribution waveguides is plural, the width direction gap between a plurality of distribution waveguides, that is, the gap between the x-axis directions, may be set to 1λ or less. This gap is determined by the array factor and is usually arranged at 0.5λ intervals, but depending on the design, it may be arranged at up to 1λ.

As described above, in the waveguide antenna structure according to an exemplary embodiment of the present disclosure, the beam pattern of the waveguide antenna structure formed with the via wall layer may be different compared to the waveguide antenna structure without the via wall layer. Hereinafter, this will be explained by using different drawings.

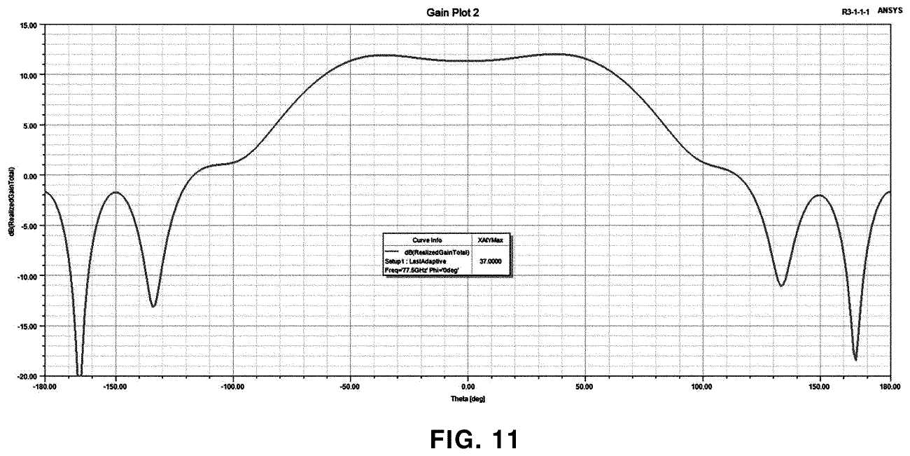

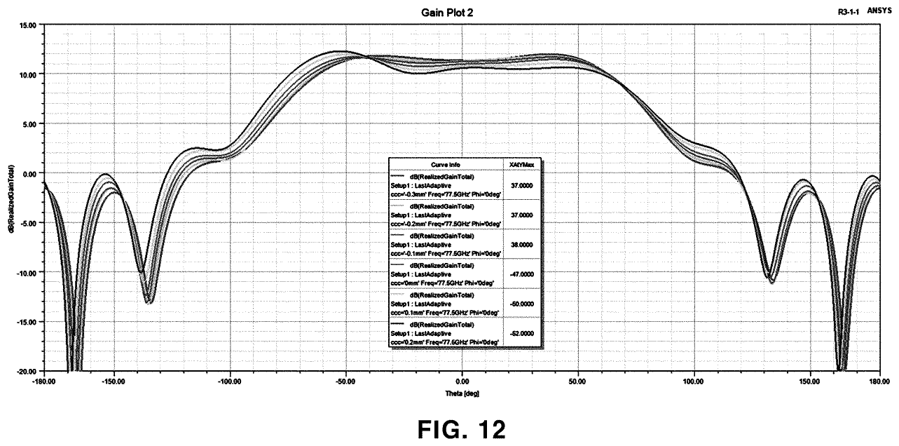

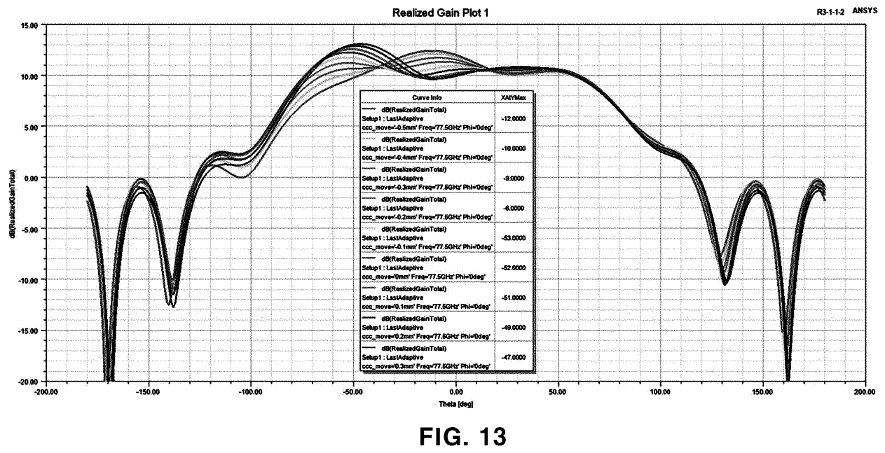

FIG. 11 is a beam pattern graph in the case where there is no via wall layer where the first via hole is formed in the PCB stacked waveguide antenna structure using a direct power feeding method according to the first example of the present disclosure. FIG. 12 is a beam pattern graph of the PCB stacked waveguide antenna using a direct power feeding method according to the first example of the present disclosure, and is a graph illustrating simulation results according to changes in height of the via wall layer. FIG. 13 is a beam pattern graph of the PCB stacked waveguide antenna using a direct power feeding method according to the first example of the present disclosure, and is a graph illustrating simulation results according to changes in the position of the via wall layer.

As can be seen with reference to FIG. 11, when using a PCB stacked waveguide antenna structure using a direct power feeding method without a via wall layer, a beam pattern graph having a gain curve with a predetermined frequency at a predetermined angle may be obtained. In the case of a waveguide antenna structure without a via wall layer, factors affecting the beam pattern may include the distance between via holes forming the waveguide, the size of the via holes, the distance between the via hole and the waveguide and the like. As such, the frequency value at a predetermined angle may vary depending on the design of the waveguide antenna.

Compared to this, as can be seen with reference to FIGS. 12 and 13, when the first via wall layer 100 is formed on the upper part of the waveguide antenna structure where the via wall layer is not formed, the pattern illustrated in FIG. 11 may be changed more variously.

Various changes in this pattern are possible because due to the presence of the first via holes 160 forming the via wall layer, the path of the beam from the antenna is tilted in the opposite direction of the first via hole 160 by the first via holes 160, that is, it can be changed.

In an exemplary embodiment of the present disclosure, as can be seen in FIGS. 12 and 13, by changing the positions of the first via holes 160 (distance between the first via hole and the second via hole (L5 in FIG. 2)) and the height (H1) of the first via hole, the tilting angle of the beam and the intensity of the tilted beam may be variously changed.

Accordingly, the waveguide antenna structure according to the first example of the present disclosure has the advantage of being able to design signals of various patterns depending on the design of the first via hole 160 as well as the second via hole 60.

Meanwhile, in an exemplary embodiment of the present disclosure, the first via wall layer 100 with the opening 101 formed to form the first via hole 160 is entirely disposed on the antenna layer 20 and the opening 101 is formed in the center of the first via wall layer 100, but it is also possible to install the fourth board 104 only in part of the antenna layer such that the first via hole 160 is formed on a side part of the antenna.

According to various exemplary embodiments of the present disclosure, the waveguide antenna structure may be changed in various ways by varying the shape of the via wall layer and the number of stacked via wall layers. Hereinafter, the waveguide antenna structure according to other exemplary embodiments of the present disclosure will be described with different drawings.

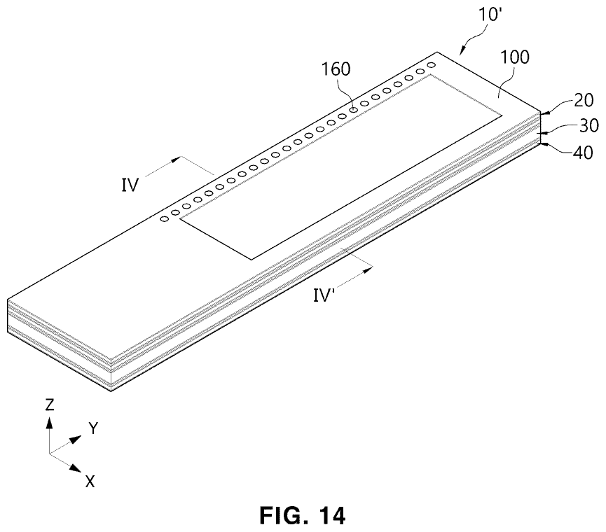

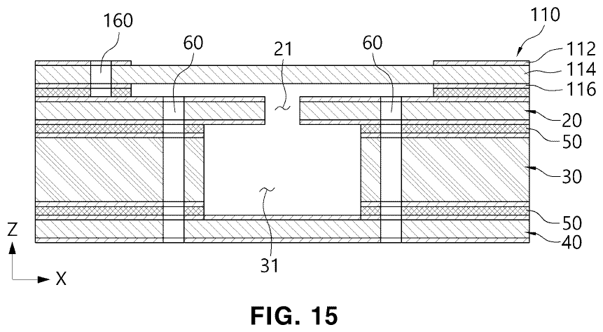

FIG. 14 is a perspective view of the PCB stacked waveguide antenna using a direct power feeding method according to the second example of the present disclosure. FIG. 15 is a cross-sectional view taken along the line IV-IV′ of FIG. 14 of the PCB stacked waveguide antenna using a direct power feeding method according to the second example of the present disclosure. Hereinafter, in terms of describing the waveguide antenna structure according to the second example of the present disclosure, it will be described by focusing on the configurations that are differentiated from the first example.

The waveguide antenna structure 10′ according to the second example of the present disclosure includes a second via wall layer 110, an antenna layer 20, a waveguide layer 30 and a base layer 40. In this case, the power supply hole in the base layer 40 is omitted in FIG. 15.

In this case, in the waveguide antenna structure 10′ according to the second example of the present disclosure, the antenna layer 20, the waveguide layer 30 and the base layer 40 may be formed by the same configurations as the first example described above.

In the waveguide antenna structure 10′ according to the second example of the present disclosure, the second via wall layer 110 may be coupled to the upper part of the antenna layer 20 by an adhesive layer 50.

In this case, the second via wall layer 110 of the waveguide antenna structure 10′ according to the second example of the present disclosure may include a fifth board 114 and a first protective layer 112 and a second protective layer 116 which are formed on the upper surface and lower surfaces of the fifth board.

In this case, the materials of the fifth board 114, the first protective layer 112 and the second protective layer 116 may be the same as those of the board and protective layers described above.

The second via wall layer 110 of the waveguide antenna structure 10′ according to the second example of the present disclosure may be provided with a first via hole 160 that is similar to the first example.

In this case, the second via wall layer 110 of the waveguide antenna structure 10 according to the second example of the present disclosure does not have an opening, unlike the first example. In more detail, the second via wall layer 110 is formed to cover the antenna hole 21 from the upper side of the antenna hole 21 without forming an opening in the fifth board 114. According to the second example of the present disclosure, no opening is formed in the fifth board 114, but the first protective layer 112 and the second protective layer 116 are formed along the rectangular arrangement of the second via holes 60 surrounding the antenna hole 21, and the first protective layer 112 and the second protective layer 116 are not formed on top of the antenna hole 21.

According to the second example of the present disclosure, since no opening is formed on the fifth board 114, the first protective layer 112 and the second protective layer 116 are formed on both side surfaces of the fifth board 114, and the waveguide antenna structure 10′ according to the second example may be manufactured through a process of forming the first via hole 160 in the fifth board 114 and bonding to the upper part of the antenna layer 20.

The waveguide antenna structure 10′ according to the second example of the present disclosure has the advantage that the manufacturing process can be simplified compared to the first example because the process of forming an opening in the fifth board 114 is not performed. In addition, since the fifth board 114 is formed on top of the antenna hole 21 to block the antenna hole 21, it is possible to prevent foreign substances from entering the antenna hole 21 from the outside.

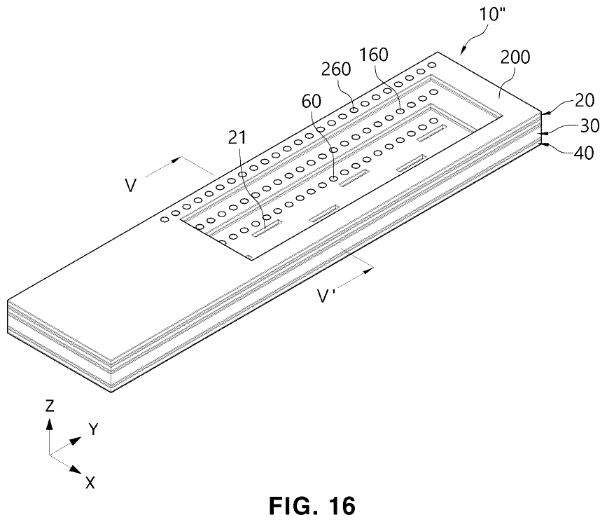

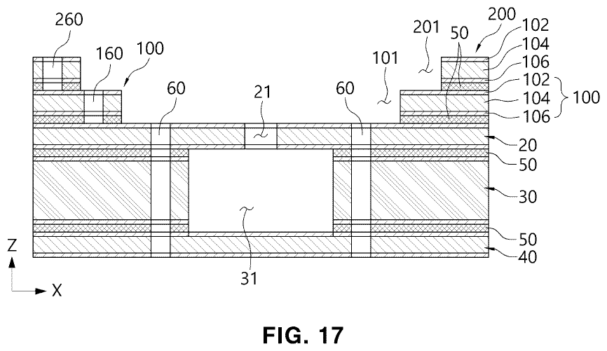

FIG. 16 is a perspective view of the PCB stacked waveguide antenna using a direct power feeding method according to the third example of the present disclosure. FIG. 17 is a cross-sectional view taken along the line V-V′ of FIG. 16 of the PCB stacked waveguide antenna using a direct power feeding method according to the third example of the present disclosure. Hereinafter, in terms of describing the waveguide antenna structure according to the third example of the present disclosure, it will be described by focusing on the configurations that are differentiated from the first example.

The waveguide antenna structure 10″ according to the third example of the present disclosure includes two stacked first via wall layers 100, 200, an antenna layer 20, a waveguide layer 30 and a base layer 40.

In this case, in the waveguide antenna structure 10″ according to the third example of the present disclosure, the antenna layer 20, the waveguide layer 30 and the base layer 40 may be formed by the same configurations as the first example described above. In this case, the illustration of a power feeding hole in the base layer 40 is omitted in FIG. 17.

In the waveguide antenna structure 10″ according to the third example of the present disclosure, two first via wall layers 100, 200 may be coupled to the top of the antenna layer 20 by an adhesive layer 50.

In this case, each of the two first via wall layers 100, 200 of the waveguide antenna structure 10″ according to the third example of the present disclosure may include a fourth board 104 and a first protective layer 102 and a second protective layer 106 which are formed on an upper surface and a lower surface of the fourth board 104. In this case, the materials of the fourth board 104, the first protective layer 102 and the second protective layer 106 may be the same as the materials of the board and protective layers described above.

The first via wall layers 100, 200 of the waveguide antenna structure 10″ according to the third example of the present disclosure may be provided with first via holes 160, 260, similar to the first example. However, the two stacked first via wall layers 100, 200 respectively have a plurality of first via holes 160, 260, and the opening 201 of the first via wall layer 200 located further above with respect to the antenna layer 20 may be formed to have a wider opening 101 than the opening of the first via wall layer 100 disposed to be in contact with the antenna layer 20. The two openings 101 and 201 may both have a rectangular shape. In this case, the two openings 101 and 201 are formed to have the same length in the extension direction of the antenna, and the length in the width direction is formed such that the opening 201 formed at the top has a wider width.

In the third example of the present disclosure, the distance and positional relationship between the first via holes 160, 260 formed in the two first via wall layers 100, 200 may be set to be identical to the distance and positional relationship between the first vial hole 160 and the second via hole 260 as described in the first example.

According to the third example of the present disclosure, the waveguide antenna structure may be configured to have a signal pattern different from the signal pattern that can appear in the waveguide antenna structure of the first example by stacking two via wall layers 100, 200.

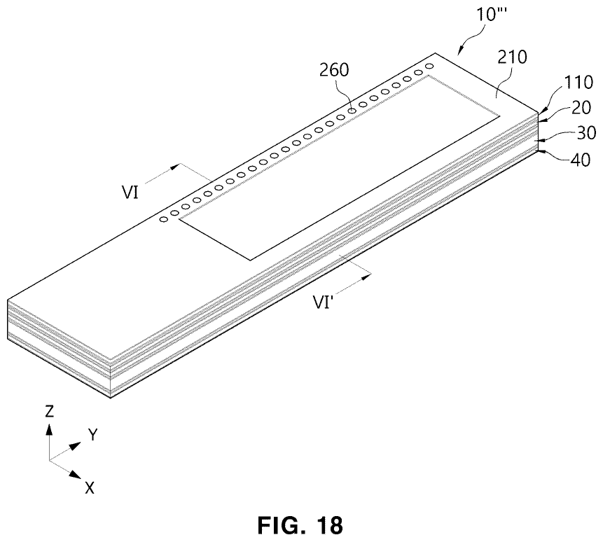

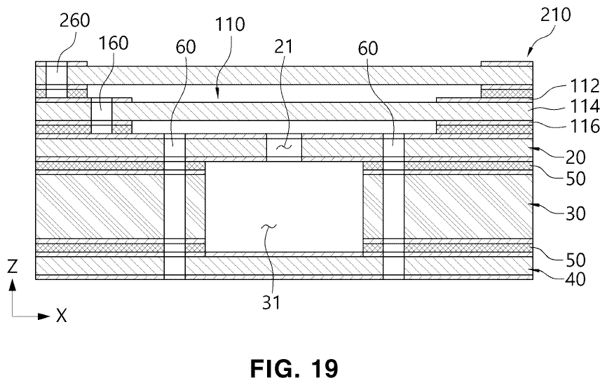

FIG. 18 is a perspective view of the PCB stacked waveguide antenna using a direct power feeding method according to the fourth example of the present disclosure. FIG. 19 is a cross-sectional view taken along the line VI-VI′ of FIG. 18 of the PCB stacked waveguide antenna using a direct power feeding method according to the fourth example of the present disclosure. Hereinafter, in terms of describing the waveguide antenna structure according to the fourth example of the present disclosure, it will be described by focusing on the configurations that are differentiated from the above-described examples.

The waveguide antenna structure 10″ according to the fourth example of the present disclosure includes two stacked second via wall layers 110, 210, an antenna layer 20, a waveguide layer 30 and a base layer 40.

In this case, in the waveguide antenna structure 10′″ according to the fourth example of the present disclosure, the antenna layer 20, the waveguide layer 30 and the base layer 40 may be formed by the same configurations as the first example described above. In this case, the illustration of a power feeding hole in the base layer 40 is omitted in FIG. 19.

In the waveguide antenna structure 10″ according to the fourth example of the present disclosure, two second via wall layers 110 may be coupled to the top of the antenna layer 20 by an adhesive layer 50.

In this case, each of the two second via wall layers 110, 210 of the waveguide antenna structure 10′″ according to the fourth example of the present disclosure includes a fifth board 114 and a first protective layer 112 and a second protective layer 116 which are formed on an upper surface and a lower surface of the fifth board 114 as already described in the above-described second example. In this case, the materials of the fifth board 114, the first protective layer 112 and the second protective layer 116 may be the same as the materials of the board and protective layers described above.

The second via wall layers 110, 210 of the waveguide antenna structure 10″ according to the fourth example of the present disclosure may be provided with first via holes 160, 260, similar to the second example.

In this case, the second via wall layers 110, 210 of the waveguide antenna structure 10″ according to the fourth example of the present disclosure do not have an opening, unlike the first example. In more detail, the second via wall layers 110, 210 are formed to cover the antenna hole 21 from the upper side of the antenna hole 21 without forming an opening in the fifth board 114.

In the fourth example of the present disclosure, the distance and positional relationship between the first via holes 160, 260 formed in the two second via wall layers 110, 210 may be set to be identical to the distance and positional relationship between the first via hole 160 and the second vial hole 260 as described in the first example.

According to the fourth example of the present disclosure, the waveguide antenna structure may be configured to have a signal pattern different from the signal pattern that can appear in the waveguide antenna structure of the second example by stacking two second via wall layers 110, 210. For example, forming two via wall layers may tilt the beam pattern more than using one wall layer compared to forming one via wall layer.

Meanwhile, as a modified example of the first example of the present disclosure, there may be various modified examples depending on changes in the arrangement and location of the first via hole 160 formed in the via wall layer.

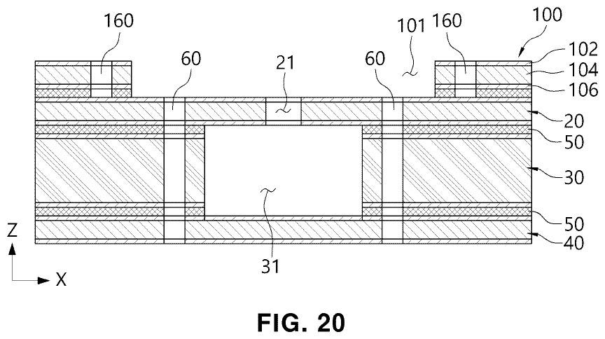

As a modified example, as illustrated in FIG. 20, via holes 60 may be arranged in a row on both side parts of the waveguide 31 in the extension direction of the waveguide 31.

Accordingly, the waveform of radio waves transmitted or received through the antenna may vary depending on whether the first via hole 160 formed in the via wall layer is formed on one side part or both side parts of the waveguide 31.

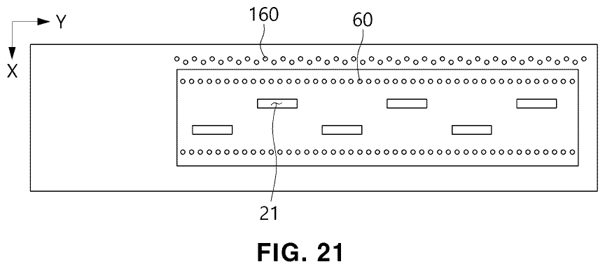

In addition, as another modified example of the first example of the present disclosure, as illustrated in FIG. 21, a plurality of first via holes 160 formed on one side part of the waveguide 31 may be arranged in two rows such that neighboring via holes in the extension direction of the waveguide 31 are staggered on one side part of the waveguide 31 in the extension direction of the waveguide 31.

In this way, arranging the first via holes 160 in one row or arranging to be staggered may be designed or selected in various ways by considering the pattern and frequency waveform of the transmitted or received signals.

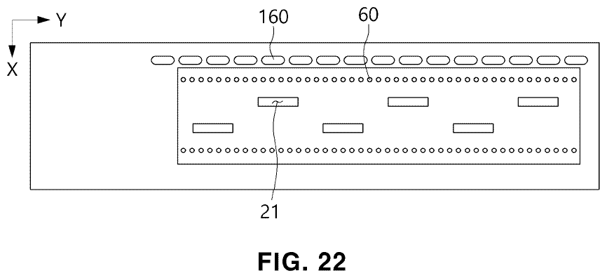

Additionally, as another modified example of the first example of the present disclosure, as illustrated in FIG. 22, the first via hole 160 may be formed in an oval shape in the extension direction of the waveguide 31. In this way, by forming the first via holes 160 in an oval shape, the number of first via holes may be variously changed. It would also be possible to change the shape of the via hole in various ways by considering the design specifications.

As described above, the waveguide antenna structure according to various examples of the present disclosure is manufactured by stacking boards, and thus, manufacturing is easy, and costs may be reduced.

In this case, it is possible to provide a waveguide antenna structure that transmits or receives signals having a desired pattern by changing the shape of the stacked board and the arrangement, size and gap of via holes formed on the board.

In addition, the waveguide antenna structure according to various examples of the present disclosure uses a material such as FR-4 to form a board and penetrates the board to form a waveguide, and thus, it is possible to simply manufacture an antenna structure including the waveguide.

In addition, the waveguide antenna structure according to various examples of the present disclosure may variously change the design of the second via hole forming the waveguide and the first via hole forming the via wall layer, and thus, it is possible to manufacture a waveguide antenna structure having a beam pattern desired by the designer.

In addition, since the waveguide antenna structure according to various examples of the present disclosure manufactures the waveguide antenna in a structure that feeds power directly to the waveguide by combining a base layer with a feeding hole directly connected to the waveguide to the waveguide layer, it has the advantage of less signal loss compared to a structure that indirectly transmits radio waves to a waveguide by using a microstrip,

According to the above configurations, the waveguide antenna structure and device according to an exemplary embodiment of the present disclosure may transmit or receive RF signals to the waveguide antenna by feeding the same directly from the MMIC chip that generates the RF signals.

Since the waveguide antenna structure according to an exemplary embodiment of the present disclosure forms a waveguide by stacking PCB boards, the antenna may be manufactured at a low price.

In addition, the waveguide antenna structure according to an exemplary embodiment of the present disclosure may change the path of an RF signal or change signal characteristics with a simple structure by stacking PCB boards and building a wall formed of via holes on the top of the waveguide antenna.

Additionally, since the waveguide antenna structure according to an exemplary embodiment of the present disclosure uses a direct power feeding method, signal loss occurring while the signal is transferred from the conventional microstrip to the waveguide may be reduced.

It should be understood that the effects of the present disclosure are not limited to the above-described effects and include all effects inferable from a configuration of the invention described in detailed descriptions or claims of the present disclosure.

Although embodiments of the present disclosure have been described, the spirit of the present disclosure is not limited by the embodiments presented in the specification. Those skilled in the art who understand the spirit of the present disclosure will be able to easily suggest other embodiments by adding, changing, deleting, or adding components within the scope of the same spirit, but this will also be included within the scope of the spirit of the present disclosure.

What is claimed is:

1. A waveguide antenna structure, comprising:
a base layer having a feeding hole;
a waveguide layer stacked on the base layer and having a waveguide communicating with the feeding hole of the base layer;
an antenna layer stacked on the waveguide layer and having an antenna configured to transmit or receive signals passing through the feeding hole of the base layer and the waveguide of the waveguide layer to or from an outside of the waveguide antenna structure; and
a first via wall layer comprising a plurality of first via holes on the antenna layer and configured to change a path of the signals transmitted or received through the antenna.

2. The waveguide antenna structure of claim 1, wherein each of the first via wall layer, the antenna layer, the waveguide layer and the base layer comprises:
a board layer; and
a first protective layer and a second protective layer stacked on one surface and another surface of the board layer, respectively.

3. The waveguide antenna structure of claim 2, wherein the board layer is made of glass epoxy material, and
wherein the first protective layer and the second protective layer have conductive material.

4. The waveguide antenna structure of claim 1, wherein:
a plurality of second via holes penetrate the base layer, the waveguide layer and the antenna layer,
the plurality of second via holes are arranged to surround the feeding hole, the waveguide and the antenna when viewed in a first direction in which the base layer, the waveguide layer, and the antenna layer are stacked, and
the plurality of first via holes of the first via wall layer are formed on a side of the antenna along an extension direction in which the waveguide extends, and are disposed at a farther distance from the antenna than the plurality of second via holes.

5. The waveguide antenna structure of claim 4, wherein the plurality of second via holes are arranged in a row in a substantially rectangular shape, and an overall arrangement length of a first group of the plurality of second via holes arranged in the extension direction in which the waveguide extends is longer than an overall arrangement length of a second group of the plurality of second via holes arranged in a direction different from the extension direction in which the waveguide extends.

6. The waveguide antenna structure of claim 5, wherein a distance between the plurality of second via holes and the plurality of first via holes is 1.5 or less of a wavelength of one of the signals.

7. The waveguide antenna structure of claim 5, wherein a height of the plurality of first via holes is 1.5 or less of a wavelength of one of the signals.

8. The waveguide antenna structure of claim 5, wherein the plurality of first via holes are arranged in a row on one side or both sides of the waveguide in the extension direction in which the waveguide extends.

9. The waveguide antenna structure of claim 5, wherein the plurality of first via holes are arranged in two rows on one side or both sides of the waveguide such that neighboring via holes of the plurality of first via holes are arranged to be staggered in the extension direction in which the waveguide extends.

10. The waveguide antenna structure of claim 5, wherein the first via wall layer has a first opening surrounding an area formed by the plurality of second via holes surrounding the feeding hole, the waveguide and the antenna, the first opening is wider than the area formed by the plurality of second via holes surrounding the feeding hole, the waveguide and the antenna, and the plurality of first via holes are located outside the first opening.

11. The waveguide antenna structure of claim 5, wherein the first via wall layer is disposed to cover the area formed by the plurality of second via holes surrounding the feeding hole, the waveguide and the antenna.

12. The waveguide antenna structure of claim 1, wherein an adhesive layer is respectively interposed between the base layer, the waveguide layer, the antenna layer and the first via wall layer.

13. The waveguide antenna structure of claim 10, further comprising:
a second via wall layer which is stacked on the first via wall layer and comprises a plurality of third via holes for changing the path of the signals,
wherein the second via wall layer has a second opening surrounding the first opening and being wider than the first opening, and the plurality of third via holes are located outside the second opening.

14. The waveguide antenna structure of claim 11, further comprising:
a second via wall layer which is stacked on the first via wall layer and comprises a plurality of third via holes for changing the path of the signals,
wherein the second via wall layer is arranged such that the second via wall layer covers the area formed by the plurality of second via holes surrounding the feeding hole, the waveguide and the antenna, and the plurality of third via holes are spaced farther apart from the plurality of second via holes than the plurality of first via holes.

15. A waveguide antenna structure, comprising:
a base layer having a feeding hole;
a waveguide layer stacked on the base layer and having a waveguide communicating with the feeding hole of the base layer;
an antenna layer stacked on the waveguide layer and having an antenna configured to transmit or receive signals passing through the feeding hole of the base layer and the waveguide of the waveguide layer to or from an outside of the waveguide antenna structure; and
one or more via wall layers stacked on the antenna layer and configured to change a path of the signals transmitted or received through the antenna.

16. The waveguide antenna structure of claim 15, wherein each of the one or more via wall layers comprises a plurality of via holes formed on a side of the antenna along an extension direction in which the waveguide extends.

17. The waveguide antenna structure of claim 16, wherein each of the plurality of via holes formed in the one or more via wall layers is arranged in a row on one side or both sides of the antenna.

18. The waveguide antenna structure of claim 16, wherein a first group of the plurality of via holes formed in the one or more via wall layers that is positioned to be closer to the antenna layer is positioned to be closer to the antenna than a second group of the plurality of via holes formed in the one or more via wall layers that is disposed farther from the antenna layer.

19. The waveguide antenna structure of claim 16, wherein each of the one or more via wall layers includes an opening surrounding the feeding hole, the waveguide and the antenna when viewed in a direction in which the base layer, the waveguide layer, and the antenna layer are stacked and an opening of one of the one or more via wall layers disposed farther from the antenna layer than another of the one or more via wall layers is wider than an opening of the another of the one or more via wall layers disposed closer to the antenna layer that the one of the one or more via wall layers.

20. The waveguide antenna structure of claim 16, wherein one of the one or more via wall layers covers the feeding hole, the waveguide and the antenna.
